(19) United States
(12) Patent Application Publication
(10) Pub. No.: US 2016/0228999 A1
(43) Pub. Date: Aug. 11, 2016

(54) FLUX AND METHOD OF MANUFACTURING ELECTRONIC DEVICE

(71) Applicant: FUJITSU LIMITED, Kawasaki-shi (JP)

(72) Inventors: Kozo Shimizu, Atsugi (JP); Nobuhiro Imaizumi, Atsugi (JP); Seiki Sakuyama, Yamato (JP)

(73) Assignee: FUJITSU LIMITED, Kawasaki-shi (JP)

(21) Appl. No.: 14/982,342

(22) Filed: Dec. 29, 2015

(30) Foreign Application Priority Data
Feb. 6, 2015 (JP) 2015-021949

(51) Int. Cl. B23K 35/36; H01L 23/00

(52) U.S. Cl. CPC B23K 35/3613; H01L 24/81; H01L 2224/81024; H01L 2224/8191; H01L 2924/06

(57) ABSTRACT

A flux used for bonding a solder includes: 75 wt % or more of ethylene glycol polymer represented by the following formula: HO(CH₂CH₂O)ₙH [n is an integer of 4 or more], wherein an evaporation of the ethylene glycol polymer while being heated is terminated at a temperature equal to or greater than a bonding temperature of the solder.

### CROSS-REFERENCE TO RELATED APPLICATION

This application is based upon and claims the benefit of priority of the prior Japanese Patent Application No. 2015-021949, filed on Feb. 6, 2015, the entire contents of which are incorporated herein by reference.

### FIELD

The embodiments discussed herein are related to a flux and a method of manufacturing an electronic device using a flux.

### BACKGROUND

There has been known a technique for bonding a solder to a terminal of an electronic component such as a semiconductor device or circuit board by using a flux. For example, there has been known a technique for bonding the solder to the terminal by reducing and removing an oxide film on the surface of the solder or the surface of the terminal of the electronic component by using a flux containing rosin. Further, a technique for cleaning a flux residue (e.g., a flux cleaning) after the solder bonding has been known.

Depending on the ingredients of the flux used for the solder bonding, in some cases, the flux residue may remain after the solder bonding or after the flux cleaning. The flux residue that remains after the solder bonding or after the flux cleaning may cause a corrosion of the solder or the solder-bonded electronic component and degradation of quality. Further, the flux residue may cause an ion migration originated therefrom, and lead to a reduction in the insulation resistance with respect to its surroundings.

The following is a reference document.

[Document 1] Japanese Laid-Open Patent Publication No. 2011-083809.

### SUMMARY

According to an aspect of the invention, a flux used for bonding a solder includes: 75 wt % or more of ethylene glycol polymer represented by the following formula: HO(CH₂CH₂O)ₙH [n is an integer of 4 or more], wherein an evaporation of the ethylene glycol polymer while being heated is terminated at a temperature equal to or greater than a bonding temperature of the solder.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A to 1C each illustrates a first example of a solder bonding method;

FIGS. 2A to 2C each illustrates a second example of a solder bonding method;

FIG. 3 is a diagram illustrating an example of a state after the solder bonding (the first example);

FIGS. 4A and 4B are diagrams illustrating an example of a state after the solder bonding (the second example);

FIG. 5 is a diagram illustrating an example of a weight reduction ratio of an ethylene glycol polymer;

FIG. 6 is a diagram illustrating an exemplary configuration of a semiconductor chip;

FIGS. 7A and 7B are diagrams illustrating an exemplary configuration of a semiconductor package (the first example);

FIG. 8 is a diagram illustrating an exemplary configuration of a semiconductor package (the second example); and

FIGS. 9A and 9B are diagrams illustrating an exemplary configuration of a circuit board.

### DESCRIPTION OF EMBODIMENTS

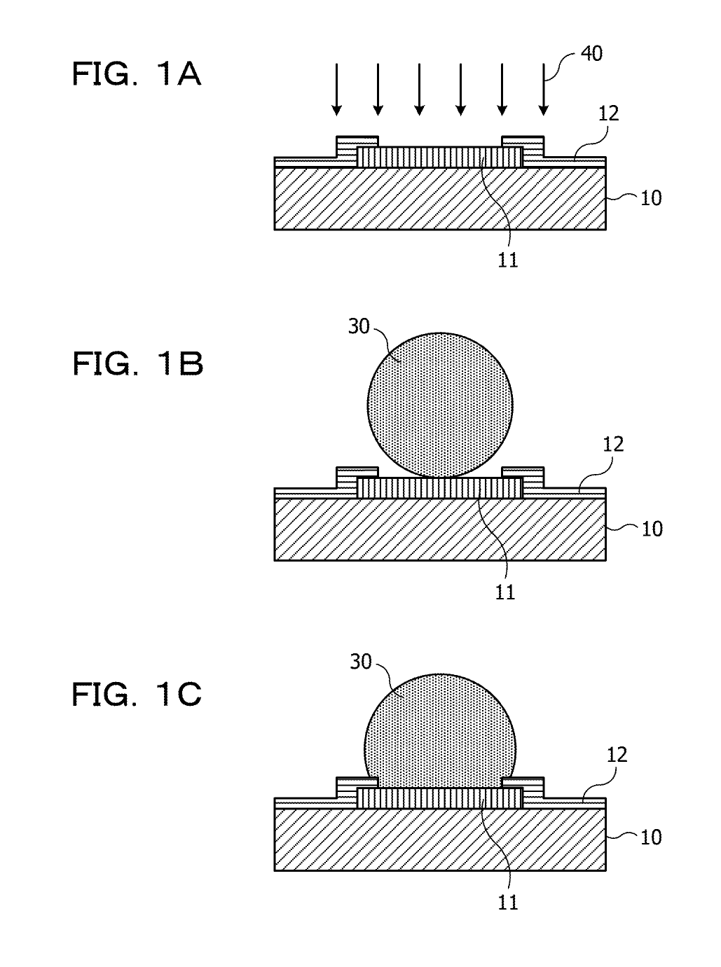

The bonding of solder will be described first. FIGS. 1A to 1C each illustrates a first example of a solder bonding method. FIG. 1A is a cross-sectional view schematically illustrating a main part of a flux disposition process according to the first example. FIG. 1B is a cross-sectional view schematically illustrating a main part of a solder disposition process according to the first example. FIG. 1C is a cross-sectional view schematically illustrating a main part of a solder bonding process according to the first example.

In this method, first, as illustrated in FIG. 1A, an electronic component 10 provided with a terminal 11 is prepared. On the disposition surface side of the terminal 11 of the electronic component 10, a protective film 12 such as a solder resist is provided to expose at least a part of the terminal 11. A flux 40 is supplied to the disposition surface side of the terminal 11 of the electronic component 10. As for the flux 40, one having a function of reducing an oxide film formed on the surface of a solder 30 to be described below and the surface of the terminal 11 is used. The flux 40 may be provided onto the electronic component 10 by using a method such as a spray method, a coating method, and a printing method.

After the supply of the flux 40, as illustrated in FIG. 1B, the solder 30 is provided on the terminal 11. As for the solder 30, for example, a solder ball may be used. In addition to the solder ball, a solder paste containing solder powder may be provided on the terminal 11 by using a method such as a printing method. In the case of using the solder paste, a flux may be contained in the solder paste.

After or while mounting the solder 30, by heating and melting the solder 30, as illustrated in FIG. 1C, the solder 30 is bonded to the terminal 11 of the electronic component 10. During the bonding, first, the flux 40 supplied to the electronic component 10 reduces and removes the oxide film formed on the surface of the terminal 11 and the surface of the solder 30. Thus, it is possible to bond the solder 30 to the terminal 11 of the electronic component 10.

By the method illustrated in FIGS. 1A to 1C, the electronic component 10 (e.g., an electronic device) is obtained in which the solder 30 is provided on the terminal 11.

Further, a plurality of terminals 11 may be provided in the electronic component 10. In this case, the solder 30 may be bonded onto each of the terminals 11 by the method illustrated in FIGS. 1A to 1C.

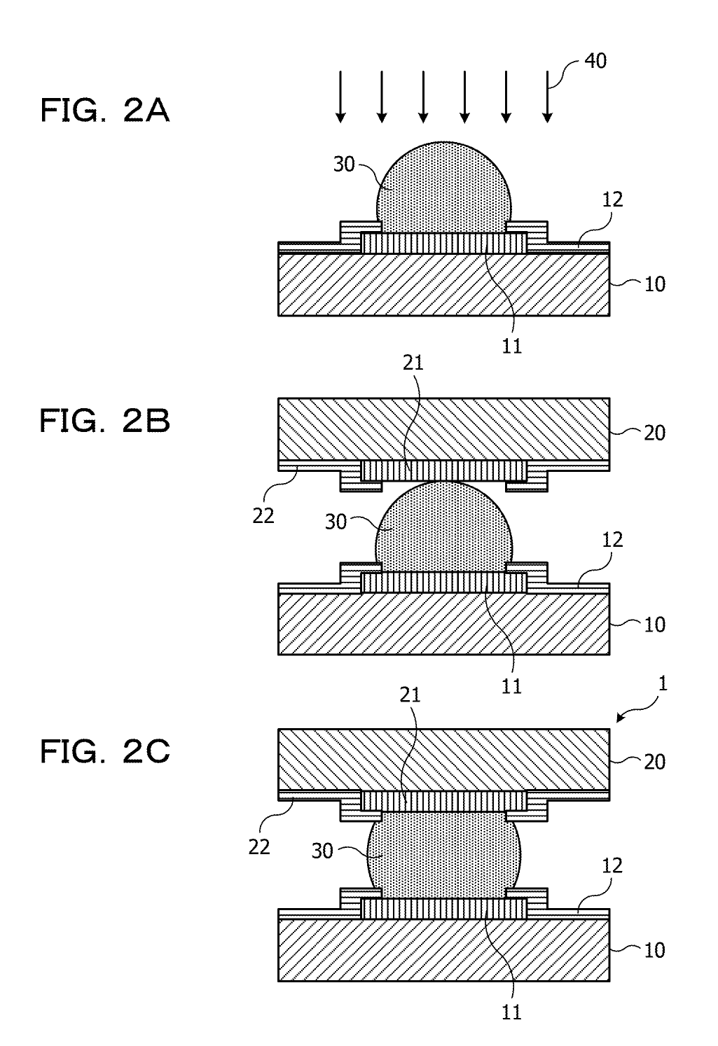

FIGS. 2A to 2C illustrate a second example of a solder bonding method. FIG. 2A is a cross-sectional view schematically illustrating a main part of a flux disposition process according to the second example. FIG. 2B is a cross-sectional view schematically illustrating a main part of a solder disposition process according to the second example. FIG. 2C is a cross-sectional view schematically illustrating a main part of a solder bonding process according to the second example.

In this method, first, as illustrated in FIG. 2A, the electronic component 10 is prepared in which the solder 30 is provided on the terminal 11 exposed from the protective film 12 and the flux 40 is supplied to the disposition surface side of the solder 30. As for the flux 40, one having a function of reducing an oxide film formed on the surface of the solder 30 and the surface of a terminal 21 to be described below is used. The flux 40 may be provided onto the electronic component 10 and the solder 30 by using a method such as a spray method.

As illustrated in FIG. 2B, an electronic component 20 provided with the terminal 21 is prepared. On the disposition surface side of the terminal 21 of the electronic component 20, a protective film 22 such as a solder resist is provided to expose at least a part of the terminal 21. The electronic component 20 is disposed to face the electronic component 10 to which the flux 40 has been supplied by performing an alignment process between the terminal 21 and the terminal 11.

In a state where the solder 30 and the terminal 21 are in contact with each other, the solder 30 is bonded to the terminal 21 of the electronic component 20 by heating and melting the solder 30 as illustrated in FIG. 2C. During the bonding, first, the flux 40 supplied to the electronic component 10 reduces and removes the oxide film formed on the surface of the terminal 21 and the surface of the solder 30. Thus, it is possible to bond the solder 30 provided on the terminal 11 of the electronic component 10 to the terminal 21 of the electronic component 20.

By the method illustrated in FIGS. 2A to 2C, an electronic device 1 is obtained in which the terminal 11 of the electronic component 10 is electrically connected to the terminal 21 of the electronic component 20 via the solder 30.

Further, a plurality of terminals 11 may be provided in the electronic component 10, and a plurality of terminals 21 may be provided in the electronic component 20 to correspond to the terminals 11 of the electronic component 10. In this case, the solder 30 provided on each of the terminals 11 may be bonded onto each of the terminals 21 by the method illustrated in FIGS. 2A to 2C.

Although it has been illustrated in FIG. 2A that the flux 40 is supplied to the side of the electronic component 10 on which the solder 30 is provided on the terminal 11, the flux 40 may be supplied to the side of the electronic component 20 on which the terminal 21 for bonding the solder 30 is provided. The flux 40 may be supplied to only the side of the electronic component 20, or may be supplied to both sides of the electronic component 10 and the electronic component 20. The electronic component 20 to which the flux 40 has been supplied is disposed to face the electronic component 10 (e.g., electronic component 10 either supplied or not supplied with the flux 40), as illustrated in FIG. 2B, by performing an alignment, and the solder 30 is bonded to the terminal 21 as illustrated in FIG. 2C.

Further, although a case of bonding the electronic component 10 in which the solder 30 is provided on the terminal 11 with the electronic component 20 on which the terminal 21 is provided has been exemplified in FIGS. 2A to 2C, the solder may also be provided on the terminal 21 of the electronic component 20 before bonding similarly to the terminal 11 of the electronic component 10 before bonding. The flux is supplied to the side of the electronic component 10 or the side of the electronic component 20, or both sides of the electronic component 10 and the electronic component 20. Then, the electronic component 20 provided with the solder on the terminal 21 is disposed to face the electronic component 10 provided with the solder 30 on the terminal 11 by performing an alignment, and the solder is bonded to the solder 30.

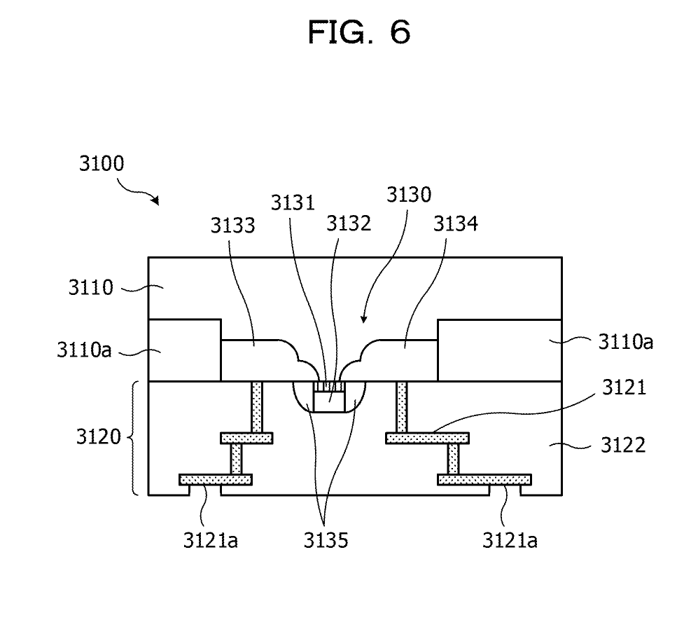

As for each of the electronic component 10 and the electronic component 20, for example, a semiconductor element (semiconductor chip), a semiconductor package having a semiconductor chip, or a circuit board may be used. Further, an exemplary configuration of the semiconductor chip, the semiconductor package, and the circuit board will be described later (see, e.g., FIGS. 6 to 9B).

For the bonding of the solder, there is a method using a flux as described above. As one type of flux used for bonding of the solder, a rosin-based flux having rosin as a main ingredient has been known. However, in the case of using the rosin-based flux, the following events may occur.

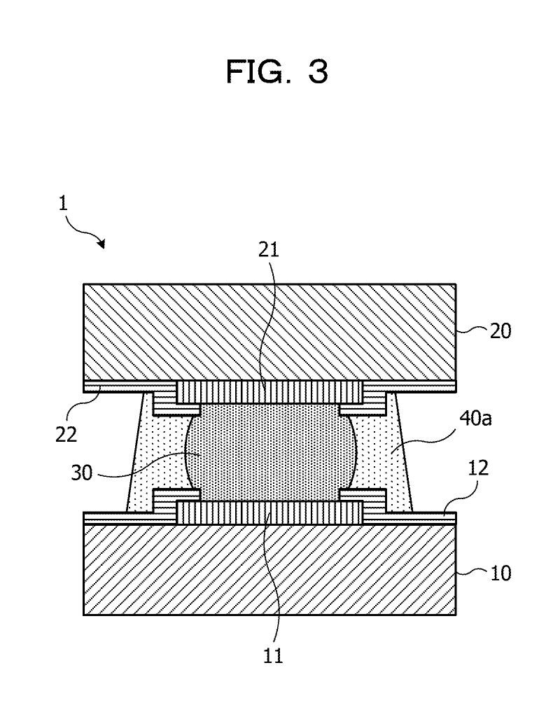

FIG. 3 is a diagram illustrating an example of a state after the solder bonding. FIG. 3 is a cross-sectional view schematically illustrating a main part of an example of an electronic device obtained by bonding electronic components with solder.

For example, by the method described above with reference to FIGS. 2A to 2C, the solder 30 provided on the terminal 11 of the electronic component 10 is bonded to the terminal 21 of the electronic component 20 using the flux 40 based on rosin. After the bonding, as illustrated in FIG. 3, a residue 40a of the flux 40 (e.g., a flux residue) that has been used may remain around the solder 30, the terminal 11, and the terminal 21 (e.g., a solder joint).

If the flux residue 40a remains in this way, a corrosion may occur in the solder 30, in the terminal 11, and in the terminal 21 by the flux residue 40a, or ion migration from the solder 30, the terminal 11, and the terminal 21 may occur during heating or during energization. The corrosion or ion migration which is attributed to the flux residue 40a may cause a reduction in the bonding strength of the solder joint, an increase in the electrical resistance of the solder joint, a reduction in the insulation resistance with respect to the peripheral conductive portions (e.g., other solder joints, etc.) and the like.

Accordingly, after bonding with the solder 30 between the terminal 11 and the terminal 21 as described above, a cleaning using isopropyl alcohol (IPA) or the like may be performed in order to remove the flux residue 40a. However, the flux residue 40a that occurs when using the rosin-based flux 40 may not be sufficiently removed by cleaning using IPA or the like. Further, the ingredients of the flux residue 40a, IPA and the like may be mixed in the protective film 12 or the protective film 22, which may cause swelling or peeling.

When a terminal pitch of the electronic component 10 and the electronic component 20 such as a semiconductor chip or a circuit board becomes finer to, e.g., 100 μm or less and the diameter of the solder 30 to be used decreases, a gap between the electronic component 10 and the electronic component 20 to be bonded through the solder 30 also becomes narrower. In this manner, it is difficult for a cleaning solution to be introduced/discharged into/from a narrow gap between the electronic components including the terminal 11 and the terminal 21 with a narrow pitch. Therefore, it may become difficult to sufficiently remove the flux residue 40a.

As for the flux, in addition to the rosin-based flux, a water-soluble flux containing halogen such as chlorine may be used. In the case of the water-soluble flux, water may be used as the cleaning solution. However, the flux residue or its ingredients may not be removed sufficiently by cleaning using water, and the flux residue may have strong corrosiveness.

In view of the above, the following flux is used for the bonding of the solder 30 in the present embodiment.

That is, in the present embodiment, as for the flux 40 to be used for the bonding of the solder 30, a flux containing 75 wt % or more of ethylene glycol polymer represented by the following formula (1) is used.

HO(CH₂CH₂O)ₙH (1)

In the formula (1), H is a hydrogen atom, C is a carbon atom, and 0 is an oxygen atom. A polymerization degree n is an integer of 4 or more.

Further, the ethylene glycol polymer of n=2, 3, 4 of the formula (1), i.e., polymers of ethylene glycol (HOCH₂CH₂OH) of two molecules, three molecules, and four molecules are diethylene glycol, triethylene glycol, and tetraethylene glycol, respectively. For convenience, the polymer of ethylene glycol of 5 or more molecules is referred to as polyethylene glycol. The flux according to the present embodiment contains 75 wt % or more, preferably, 80 wt % or more, of polymers (n≧4) of ethylene glycol of 4 or more molecules, i.e., tetraethylene glycol (TEG) and dpolyethylene glycol (PEG).

The flux according to the present embodiment may contain a viscosity modifier in addition to the ethylene glycol polymers. As the viscosity modifier, for example, an epoxy resin is used.

Moreover, the flux according to the present embodiment may contain an activator. As for the activator, for example, organic acid or organic acid anhydride is used. As for the organic acid or organic acid anhydride used as an activator, carboxylic acid or carboxylic acid anhydride, such as succinic acid, glutaric acid, adipic acid, succinic anhydride, glutaric anhydride, and abietic acid, may be mentioned.

In the adjustment and selection of the flux used in the bonding of the solder, first, a temperature condition (e.g., a bonding temperature) at the time of bonding is determined from a type of the solder (e.g., its melting point) for bonding, and a type of the ethylene glycol polymer (e.g., molecular weight or average molecular weight, evaporation temperature) is determined based on the bonding temperature. In this case, the bonding temperature of the solder is set to the melting point of the solder, or a temperature slightly higher than the melting point of the solder, e.g., about 10° C.-50° C. higher temperature, for manufacturing. In addition, the evaporation temperature of the ethylene glycol polymer tends to increase with an increase in the molecular weight or average molecular weight (hereinafter simply referred to as molecular weight).

In the case of using a flux for the bonding of the solder, the ethylene glycol polymer exhibiting a reducing action is required to entirely or partially cover the surface of the solder or the terminal to which the solder is to be bonded when the solder is heated to a predetermined bonding temperature. When the ethylene glycol polymer is not present on the surface of the solder or the terminal, the reducing action of the ethylene glycol polymer may not be exerted, a function of the flux may not be obtained, and the solder and the terminal may not be bonded to each other. Thus, it is necessary for all the ethylene glycol polymer in the flux not to be evaporated (volatilized) at a temperature lower than the bonding temperature of the solder. In other words, it is necessary for the evaporation of the ethylene glycol polymer in the flux due to the heating at the time of bonding not to be terminated until it reaches a temperature equal to or greater than the bonding temperature of the solder. By using the ethylene glycol polymer having a molecular weight and an evaporation temperature to exhibit these properties with respect to the bonding temperature of the solder, the flux is adjusted or flux containing such ethylene glycol polymer is selected.

Meanwhile, it is preferable that the ethylene glycol polymer in the flux is present on the surface of the solder or the terminal until it reaches the bonding temperature of the solder, and evaporates such that the remaining amount is small or disappears at the end of bonding, i.e., at the end of heating (e.g., at the start of cooling). In short, it is more preferable that the amount of the ethylene glycol polymer that remains as a flux residue after the solder bonding is smaller. This is because the cleaning after bonding may be unnecessary if the remaining amount of the ethylene glycol polymer is smaller or disappears at the end of the solder bonding. If the flux is adjusted by using an ethylene glycol polymer having a molecular weight and an evaporation temperature to exhibit these properties with respect to the bonding temperature of the solder, or a flux containing the ethylene glycol polymer is selected, it may be used as a no-clean flux.

However, even if the ethylene glycol polymer remains without evaporation at the end of the solder bonding, since the ethylene glycol polymer itself is soluble in water, the ethylene glycol polymer remaining after the bonding may be removed by cleaning using water. Therefore, even if the ethylene glycol polymer remains after the bonding, as compared to the cleaning using IPA or the like of the flux residue that occurs when using the rosin-based flux as described above, the flux residue may be easily cleaned and removed.

As described above, the evaporation temperature of the ethylene glycol polymer tends to increase with an increase in the molecular weight. For example, the ethylene glycol polymer having a small molecular weight and a low evaporation temperature may be applied to the bonding of the solder having a low melting point and a low bonding temperature. For example, the ethylene glycol polymer having a large molecular weight and a high evaporation temperature may be applied to the bonding of the solder having a high melting point and a high bonding temperature.

The flux is adjusted such that the content of the ethylene glycol polymer having a molecular weight based on the bonding temperature of the solder is greater than 75 wt %, or a flux is selected such that the content of the ethylene glycol polymer having a molecular weight based on the bonding temperature of the solder is greater than 75 wt %. The remainder of the flux may be constituted by a viscosity modifier or an activator. When the content of the ethylene glycol polymer in the flux is 75 wt % or less, the amount of the ethylene glycol polymer present on the surface of the solder or the terminal is small, and a sufficient reducing action of the ethylene glycol polymer may not be obtained. In order to obtain a sufficient reducing action, it is preferable that the flux contains 75 wt % or more of the ethylene glycol polymer having a predetermined molecular weight, and more preferably, 80 wt % or more. Further, since the content of an ingredient, such as a viscosity modifier, which is hardly soluble in water decreases as the composition of the ethylene glycol polymer increases, it is possible to further suppress the residues remaining after the cleaning in the case of performing a cleaning using water.

By using the flux containing 75 wt % or more of the ethylene glycol polymer having a predetermined molecular weight, the solder bonding described above with reference to FIGS. 1A to 2C is carried out.

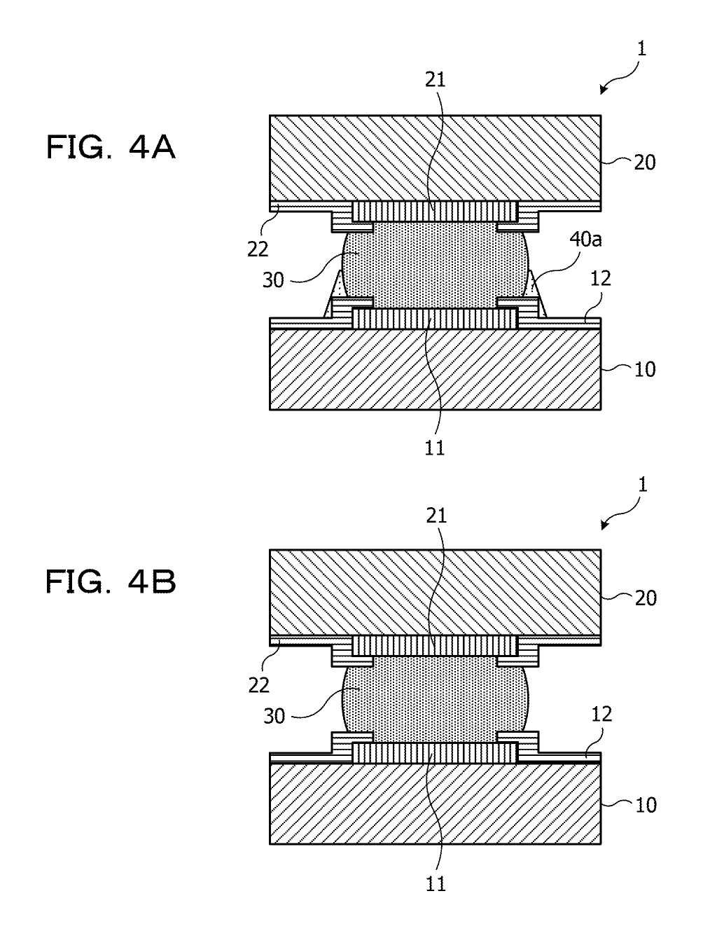

FIGS. 4A and 4B are diagrams illustrating an example of a state after the solder bonding. FIGS. 4A and 4B are cross-sectional views schematically illustrating a main part of an example of an electronic device obtained by bonding electronic components with solder.

For example, as for the flux 40 described above with reference to FIGS. 2A to 2C, the flux containing 75 wt % or more of the ethylene glycol polymer having a predetermined molecular weight is used, and the solder 30 provided on the terminal 11 of the electronic component 10 is bonded to the terminal 21 of the electronic component 20. After the bonding, for example, a state where the flux residue 40a is small as illustrated in FIG. 4A, or a state where there is no flux residue as illustrated in FIG. 4B may be obtained. The flux containing 75 wt % or more of the predetermined ethylene glycol polymer may be used as a low-residue flux or a no-clean flux.

For the selection of the ethylene glycol polymer that is contained in the flux, it is preferable that information about the weight change due to heating of the ethylene glycol polymer is obtained in advance.

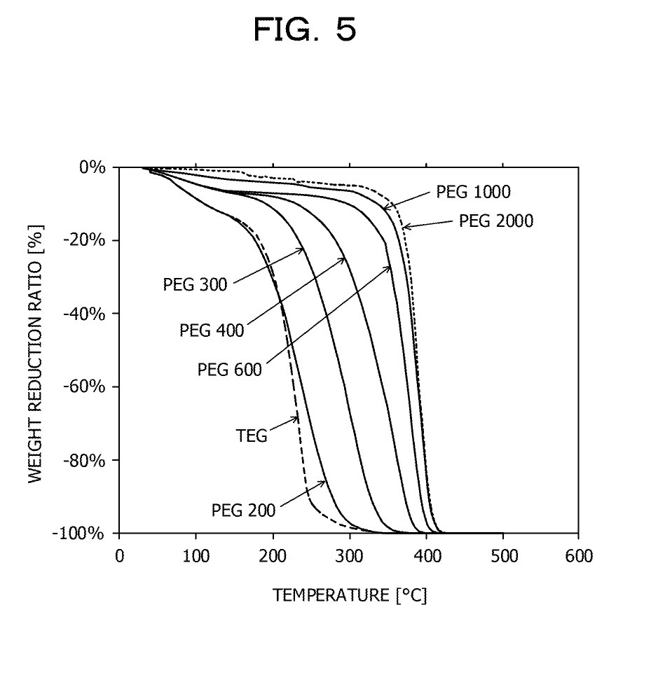

FIG. 5 is a diagram illustrating an example of a weight reduction ratio of the ethylene glycol polymer.

In FIG. 5, a horizontal axis represents a temperature [° C.], and a vertical axis represents a weight reduction ratio [%]. FIG. 5 illustrates an example of a result of measuring a weight reduction ratio of the ethylene glycol polymer when a certain amount of the ethylene glycol polymer (TEG, PEG) is heated to raise the temperature from room temperature to 500° C.

In FIG. 5, TEG is tetraethylene glycol (n=4).

PEG200 is polyethylene glycol having an average molecular weight of 200.

PEG300 is polyethylene glycol having an average molecular weight of 300.

PEG400 is a polyethylene glycol having an average molecular weight of 400.

PEG600 is polyethylene glycol having an average molecular weight of 600.

PEG1000 is polyethylene glycol having an average molecular weight of 1000.

PEG2000 is polyethylene glycol having an average molecular weight of 2,000.

In FIG. 5, the weight reduction trend of the ethylene glycol polymer in accordance with an increase in the temperature due to heating is different from each other depending on the type of the ethylene glycol polymer (e.g., depending on the molecular weight of the ethylene glycol polymer). As the molecular weight of the ethylene glycol polymer increases, the temperature at which the weight begins to decrease rapidly by evaporation shifts to the high temperature side, and the temperature at which the weight reduction ratio is 100% (e.g., the temperature at which all of the ethylene glycol polymer has been evaporated) shifts to the high temperature side.

After obtaining information illustrated in FIG. 5, it is possible to select the molecular weight of the ethylene glycol polymer used for the flux based on the bonding temperature of the solder to be bonded, and, for example, based on the temperature at which the weight reduction ratio is 100% or a predetermined weight reduction ratio of 50%. In other words, the molecular weight of the ethylene glycol polymer is selected at which the ethylene glycol polymer remains on the surface of the solder or the terminal until the temperature reaches the bonding temperature. Alternatively, by selecting the molecular weight of the ethylene glycol polymer at which the remaining amount is small or disappears at the end of heating (e.g., at the start of cooling) during the bonding, a flux having a composition to be used as a low-residue flux or a no-clean flux may be realized.

The bonding temperature of the solder, such as Sn-based solder to which an element such as bismuth (Bi) and indium (In) has been added, which is referred to as so-called a low melting point solder, exceeds 100° C. Further, in FIG. 5, when the bonding temperature exceeds 400° C., the amount of the ethylene glycol polymer remaining on the surface of the solder or the terminal is reduced and a sufficient reducing action may not be obtained. In view of this point, the bonding temperature of the solder in the case of applying the flux using the ethylene glycol polymer may be, for example, in a range of 100° C. to 400° C.

Next, examples will be explained.

TABLE 1

| | | | Flux | Flux |
|---|---|---|---|---|
| | Flux | Solder- | residue | clean- |
| | ingredient | ability | amount | ability |
| Comparative | Rosin-based flux | ◯ | Large | X |
| Example 1 | | | | |
| Comparative | Water-soluble flux | ◯ | Small | X |
| Example 2 | (containing halogen) | | | |
| Comparative | Ethylene glycol | X | — | — |
| Example 3 | | | | |
| Comparative | Diethylene glycol | X | — | — |
| Example 4 | | | | |
| Comparative | Diethylene glycol | X | — | — |
| Example 5 | dimethyl ether | | | |
| Comparative | Diethylene glycol diethyl | X | — | — |
| Example 6 | ether | | | |
| Comparative | Triethylene glycol | X | — | — |
| Example 7 | | | | |
| Example 1 | Tetraethylene glycol | Δ | Small | ◯ |
| Example 2 | Polyethylene glycol 200 | ◯ | Small | ◯ |
| Example 3 | Polyethylene glycol 300 | ◯ | Small | ◯ |
| Example 4 | Polyethylene glycol 400 | ◯ | Small | ◯ |
| Example 5 | Polyethylene glycol 600 | ◯ | Medium | ◯ |
| Example 6 | Polyethylene glycol 1000 | ◯ | Medium | ◯ |
| Example 7 | Polyethylene glycol 1540 | ◯ | Large | ◯ |
| Example 8 | Polyethylene glycol 2000 | ◯ | Large | ◯ |
| Example 9 | Polyethylene glycol 300 + | ◯ | Small | ◯ |
| | Succinic acid | | | |
| Example 10 | Polyethylene glycol 300 + | ◯ | Small | ◯ |
| | L-glutaric acid | | | |
| Example 11 | Polyethylene glycol 300 + | ◯ | Small | ◯ |
| | Adipic acid | | | |
| Example 12 | Polyethylene glycol 300 + | ◯ | Small | ◯ |
| | Succinic anhydride | | | |
| Example 13 | Polyethylene glycol 300 + | ◯ | Small | ◯ |
| | Glutaric anhydride | | | |
| Example 14 | Polyethylene glycol 300 + | ◯ | Small | ◯ |
| | Abietic acid | | | |

In the case of obtaining the results in Table 1, by using the method as illustrated in FIGS. 1A to 1C, the flux is supplied onto an electronic component provided with a group of terminals (FIG. 1A), and the solder is provided on each of the terminals (FIG. 1B) and heated to a predetermined bonding temperature (FIG. 1B), thereby performing the bonding of the solder.

The terminal is formed of copper (Cu). The solder is formed of Sn—Ag—Cu solder mainly containing tin (Sn) along with silver (Ag) and copper (Cu) (e.g., Ag: 3.0 wt %, Cu: 0.5 wt %). The melting point of the Sn—Ag—Cu solder is 217° C., and the heating is carried out in a nitrogen (N₂) atmosphere under the conditions of 240° C. to 250° C., in this case, 245° C. That is, the bonding temperature in this case is 245° C.

As for the flux to be used to bond the terminal and the solder, a flux containing ethylene glycol polymer is used. Then, the solderability, the flux residue amount before cleaning after bonding, and the flux cleanability after bonding were evaluated. An example of the results is represented in each of Examples 1 to 14 in Table 1.

In Table 1, for comparison, an example of the results when using a rosin-based flux as the flux is represented in Comparative Example 1, and an example of the results when using a water-soluble flux containing halogen as the flux is represented in Comparative Example 2.

Further, in Table 1, for comparison, the results when using, as the flux, ethylene glycol, diethylene glycol, diethylene glycol dimethyl ether, diethylene glycol diethyl ether and triethylene glycol are represented in Comparative Examples 3 to 7.

“Solderability” of Table 1 was evaluated as “0” when the solder was bonded to all the terminals, as “A” when the solder was not bonded to some of the terminals, and as “x” when the solder was not bonded to all the terminals.

“Flux residue amount” of Table 1 was evaluated by inspecting the appearance of the solder-bonded terminals with the naked eye, and is indicated as “Small,” “Large” and “Medium” when the amount is small, large and medium, respectively. When the flux residue amount is indicated as small, the electronic component may be used as a product even without cleaning. When the flux residue amount is indicated as large, it is preferable to perform cleaning in order to use the electronic component as a product.

“Flux cleanability” of Table 1 was indicated as “0” when it was possible to sufficiently remove the flux residue by performing cleaning after the solder bonding, and as “x” when it was not possible to sufficiently remove the flux residue by performing cleaning after the solder bonding. For the cleaning when using the ethylene glycol polymers of Examples 1 to 14 and when using the water-soluble flux of Comparative Example 2, water was used as a cleaning solution. For cleaning when using the rosin-based flux of Comparative Example 1, IPA was used as a cleaning solution.

Further, in Comparative Examples 3 to 7, since the solder was not bonded to the terminals, the evaluation of the flux residue amount and the flux cleanability was not performed.

In Comparative Examples 3 to 7 and Examples 1 to 8, those described in “Flux ingredient” of Table 1 were used as the flux, and additives such as a viscosity modifier and an activator were not contained.

In Examples 9 to 14, those containing polyethylene glycol having an average molecular weight of 300, and 5 wt % to 20 wt % of succinic acid, L-glutaric acid, adipic acid, succinic anhydride, glutaric anhydride and abietic acid, as an activator, were used as the flux.

Numerals 200, 300, 400, 600, 1000, 1540 and 2000 following the polyethylene glycol described in “Flux ingredient” of Table 1 represent the average molecular weight of the polyethylene glycol.

With regard to Table 1, the results of Comparative Examples 1 to 7 are described first.

In the case of using the rosin-based flux as the flux of Comparative Example 1, although the solderability was good because the solder was bonded to all the terminals, the flux residue amount was large, and it was not possible to sufficiently remove the flux residue even by cleaning using IPA.

In the case of using the water-soluble flux containing halogen as the flux of Comparative Example 2, although the solderability was good because the solder was bonded to all the terminals and the flux residue amount was small, it was not possible to sufficiently remove the flux residue by cleaning using water.

In the case of using, as the flux, ethylene glycol of Comparative Example 3, diethylene glycol (n=2) of Comparative Example 4 and triethylene glycol (n=3) of Comparative Example 7, the solder was not bonded to all the terminals and the solderability was not observed. Likewise, in the case of using diethylene glycol derivatives, i.e., diethylene glycol dimethyl ether of Comparative Example 5 diethylene glycol diethyl ether of Comparative Example 6, the solder was not bonded to all the terminals and the solderability was not observed.

Subsequently, the results of Examples 1 to 14 are described. In the case of using, as the flux, tetraethylene glycol of Example 1, although the solderability indicates that the solder was not bonded to some of the terminals, the flux residue amount was small, and the cleanability was good due to its water solubility.

As illustrated in FIG. 5, under the condition that the bonding temperature is 245° C. at which the results of Table 1 were obtained, the weight reduction ratio of tetraethylene glycol (TEG) is 90% or more. Therefore, it is considered that in the case of tetraethylene glycol, evaporation proceeds until the temperature reaches the bonding temperature of 245° C., and the amount of tetraethylene glycol present on the surface of the solder or the terminal becomes small and fails to sufficiently exhibit a reducing action at the bonding point of 245° C. Meanwhile, since the evaporation proceeds in this way and the amount of tetraethylene glycol present on the surface of the solder or the terminal becomes small at the bonding point of 245° C., the flux residue amount is considered to become small.

In the case of the solder bonding, such as Sn-based solder to which an element such as Bi or In has been added, to be performed at a lower bonding temperature than Sn—Ag—Cu solder, the amount of tetraethylene glycol present on the surface of the solder or the terminal increases and may exhibit a sufficient reducing action at the bonding point. Further, the flux residue amount may increase due to the low bonding temperature, but it is possible to relatively and easily remove the flux residue by cleaning using water.

Further, in the case of using, as the flux, polyethylene glycol 200 of Example 2, polyethylene glycol 300 of Example 3, and polyethylene glycol 400 of Example 4, the solderability was good because the solder was bonded to all the terminals. The flux residue amount was small, and the cleanability was also good due to its water solubility.

It is believed from FIG. 5 that a certain amount of polyethylene glycol (PEG200, PEG300, PEG400) of Examples 2 to 4 is present on the surface of the solder or the terminal even at the bonding temperature of 245° C. Therefore, it is possible to suppress the flux residue amount by evaporation while obtaining a sufficient reducing action.

In the case of using, as the flux, polyethylene glycol 600 of Example 5 and polyethylene glycol 1000 of Example 6, the solderability was good because the solder was bonded to all the terminals. The flux residue amount was medium, but the cleanability was good due to its water solubility.

It is believed from FIG. 5 that a still larger amount of polyethylene glycol (PEG600, PEG1000) of Examples 5 and 6 than polyethylene glycol (PEG200, PEG300, PEG400) of Examples 2 to 4 is present on the surface of the solder or the terminal even at the bonding temperature of 245° C. Therefore, it is considered that while it is possible to obtain a sufficient reducing action, the flux residue amount increases. However, it is possible to relatively and easily remove the flux residue by cleaning using water.

In the case of using, as the flux, polyethylene glycol 1540 of Example 7 and polyethylene glycol 2000 of Example 8, the solderability was good because the solder was bonded to all the terminals. The flux residue amount becomes larger than the case of using polyethylene glycol 600 of Example 5 or polyethylene glycol 1000 of Example 6, but the cleanability was good due to its water solubility.

It is believed from FIG. 5 that the same or larger amount of polyethylene glycol (PEG2000) of Example 8 than polyethylene glycol (PEG1000) of Example 6 is present on the surface of the solder or the terminal even at the bonding temperature of 245° C. Therefore, in the polyethylene glycol 1540 of Example 7 or the polyethylene glycol 2000 of Example 8, it is considered that the flux residue amount increases while it is possible to obtain a sufficient reducing action.

In the solder bonding to be performed at a higher bonding temperature than the bonding temperature of 245° C. at which the results of Table 1 were obtained, the amount of polyethylene glycol, as used in Examples 5 to 8, present on the surface of the solder or the terminal is reduced at the bonding point. Thus, it is possible to reduce the flux residue amount.

In the case of using, as the flux, materials obtained by adding various types of organic acids or organic acid anhydrides to polyethylene glycol 300, as in Examples 9 to 14, the solderability was good because the solder was bonded to all the terminals. The flux residue amount was small, and the cleanability was also good due to its water solubility.

For each of various types of polyethylene glycol, there is a temperature at which activity increases and a sufficient reducing action may be easily obtained. For example, the temperature is 233° C. for tetraethylene glycol, 240° C. for polyethylene glycol 200, 292° C. for polyethylene glycol 300, 360° C. for polyethylene glycol 400, 380° C. for polyethylene glycol 600, and 393° C. for polyethylene glycol 1000. It is about 290° C. for the materials obtained by adding various types of organic acids or organic acid anhydrides to polyethylene glycol 300. Further, it is 180° C. for diethylene glycol, 78° C. for diethylene glycol dimethyl ether, and 203° C. for triethylene glycol. As the bonding temperature of the solder is closer to the temperature at which high activity is obtained easily, a high reducing action is obtained. When selecting ethylene glycol polymer to be used in the flux, it is preferable to consider the temperature at which high activity is obtained easily in addition to a relationship between the solder bonding temperature and the molecular weight of the ethylene glycol polymer.

Further, examples will be described.

As a first example, a semiconductor device having a solder bump diameter of 40 μm and a pitch of 80 μm and a circuit board provided with a terminal having the same pitch of 80 μm were bonded to each other by using, in the flux, polyethylene glycol having an average molecular weight of 200-1000 as illustrated in Examples 1 to 6 of Table 1. By using Sn—Ag—Cu solder (e.g., having a melting point at 217° C.) as a solder bump, the solder bump of the semiconductor device was disposed to face the terminal of the circuit board, and bonding between the solder bump and the terminal was carried out by performing a reflow in a N₂ atmosphere. The bonding temperature was 245° C. After confirming that there is no electrical problem with an electronic device obtained by the bonding, a temperature cycle test of −55° C.-125° C. was conducted 500 cycles. As a result, a resistance increase was 10%, which is satisfactory. Even when the same temperature cycle test was conducted on an electronic device with no electrical problem after leaving the electronic device for 1000 hours under an environment of 121° C. and humidity of 85%, a resistance increase was 10% or less, which is satisfactory.

As a second example, a semiconductor device having a solder bump diameter of 40 μm and a pitch of 80 μm and a circuit board provided with a terminal having the same pitch of 80 μm were bonded to each other by using, in the flux, polyethylene glycol having an average molecular weight of 300, to which organic acid or organic acid anhydride has been added, as illustrated in Examples 9 to 14 of Table 1. By using Sn—Ag—Cu solder (e.g., having a melting point at 217° C.) as a solder bump, the solder bump of the semiconductor device was disposed to face the terminal of the circuit board, and bonding between the solder bump and the terminal was carried out by performing a reflow in a N₂ atmosphere. The bonding temperature was 245° C. After confirming that there is no electrical problem with an electronic device obtained by the bonding, a temperature cycle test of −55° C.-125° C. was conducted 500 cycles. As a result, a resistance increase was 10%, which is satisfactory. Even when the same temperature cycle test was conducted on an electronic device with no electrical problem after leaving the electronic device for 1000 hours under an environment of 121° C. and humidity of 85%, a resistance increase was 10% or less, which is satisfactory. Further, a high acceleration life test was conducted on an electronic device with no electrical problem at 130° C., humidity of 85% and a bias of 4V and, as a result, it was confirmed that there was no deterioration of the insulation resistance even after 96 hours.

By using the flux containing 75 wt % or more of the ethylene glycol polymer, a good solderability is obtained, and an electronic device with excellent connection reliability is obtained. Further, an example of the composition of the flux containing 75 wt % or more of the ethylene glycol polymer is represented in Table 2.

TABLE 2

| | Main | | | | | | |
|---|---|---|---|---|---|---|---|
| | ingredient | Viscosity | | | | | |
| | (wt %) | modifier | | Activator (wt %) | | | |
| | Polyeth- | (wt %) | | Succinic | Glutaric | | L- |
| | ylene | Ep- | Ep- | anhy- | anhy- | Adipic | glutaric |
| Flux | glycol 300 | oxy-1 | oxy-2 | dride | dride | acid | acid |
| 1 | 75 | 10 | 10 | 5 | — | — | — |
| 2 | 75 | 10 | 10 | — | 5 | — | — |
| 3 | 75 | 10 | 10 | — | — | 5 | — |
| 4 | 75 | 10 | 10 | — | — | — | 5 |

For example, as the flux, a material obtained by adding 10 wt % of each of two types of epoxy (epoxy-1, 2) as a viscosity modifier and 5 wt % of one of various activators to 75 wt % of the ethylene glycol polymer may be used. The viscosity modifier was added to allow the flux to have high viscosity so that the ethylene glycol polymer exhibiting a reducing action may easily remain on the surface of the solder or the like. An activator such as succinic anhydride, glutaric anhydride, adipic acid and L-glutaric acid was added to improve the solder wettability, the solderability, the flux cleanability and the like.

After selecting the molecular weight of the ethylene glycol polymer based on the solder bonding temperature, it is possible to adjust the flux to be used for the solder bonding by adding a predetermined amount of the viscosity modifier or the activator to 75 wt % or more of the ethylene glycol polymer, for example, as represented in Table 2.

As described above, in the present embodiment, as the flux used for the solder bonding, a flux containing 75 wt % or more of ethylene glycol polymer having a polymerization degree of 4 or more is used. In this case, the molecular weight of the ethylene glycol polymer in the flux is selected based on the solder bonding conditions, and is selected at which all the ethylene glycol polymer does not evaporate at a temperature below the solder bonding temperature, namely, the evaporation is not terminated until it reaches a temperature equal to or greater than the solder bonding temperature.

By using the flux mainly containing the ethylene glycol polymer, it is possible to achieve good solderability. Moreover, by appropriately selecting the molecular weight with respect to the bonding temperature, it is possible to suppress the flux residue. Even though the flux residue remains after bonding, the flux residue may be removed by cleaning using water.

The flux according to the present embodiment does not contain rosin, a thixotropic agent which causes the flux residue and amine salt which is one ingredient of an activator, or may contain only a very small amount thereof. Therefore, it is possible to suppress the occurrence of the flux residue which is difficult to be removed even by cleaning using a cleaning solution such as IPA. Further, it is possible to realize a flux which does not contain harmful ingredients for the protective film such as a solder resist.

The flux according to the present embodiment contains the ethylene glycol polymer as a main ingredient, and the flux residue is mainly formed of the ethylene glycol polymer. Therefore, by appropriately selecting the molecular weight with respect to the bonding temperature and allowing the ethylene glycol polymer to act as the flux and also evaporate until cooling after heating, the flux residue may be reduced or eliminated. Thus, it may be used as a low-residue flux or a no-clean flux. Even though the flux residue occurs, the flux residue which is mainly formed of the ethylene glycol polymer may be removed by cleaning using water, and it may be unnecessary to use an organic solvent such as IPA in the cleaning.

According to the flux containing a predetermined amount of predetermined ethylene glycol polymer, it is possible to achieve an electronic device with high reliability and high characteristics by suppressing the occurrence of corrosion or ion migration caused by a flux residue and defects such as a reduction in the insulation resistance.

Further, as long as the flux contains 75 wt % or more of ethylene glycol polymer having a polymerization degree of 4 or more and all of the flux does not evaporate at a temperature below the solder bonding temperature, the flux may contain plural types of molecular weights, plural types of average molecular weights of ethylene glycol polymers.

In the foregoing, the flux using an ethylene glycol polymer has been described. As for the electronic components 10 and 20 and the like to be bonded using the flux, as described above, a semiconductor chip, a semiconductor package including a semiconductor chip, or a circuit board may be used. An exemplary configuration of a semiconductor chip, a semiconductor package, and a circuit board will be described with reference to FIGS. 6 to 9 below.

FIG. 6 is a diagram illustrating an exemplary configuration of a semiconductor chip. FIG. 6 is a cross-sectional view schematically illustrating a main part of a semiconductor chip.

A semiconductor chip 3100 illustrated in FIG. 6 includes a semiconductor substrate 3110 in which elements such as transistors are provided, and a wiring layer 3120 provided on the semiconductor substrate 3110.

As for the semiconductor substrate 3110, in addition to a substrate such as silicon (Si), germanium (Ge), and silicon germanium (SiGe), a substrate such as gallium arsenide (GaAs) and indium phosphide (InP) are used. In the semiconductor substrate 3110, elements such as transistors, capacitors and resistors are provided. As an example of the element, a metal oxide semiconductor (MOS) transistor 3130 is illustrated in FIG. 6.

The MOS transistor 3130 is provided in an element region defined by an element isolation region 3110a provided on the semiconductor substrate 3110. The MOS transistor 3130 includes a gate electrode 3132 formed on the semiconductor substrate 3110 through a gate insulating film 3131, and a source region 3133 and a drain region 3134 formed on both sides of the gate electrode 3132 in the semiconductor substrate 3110. On the sidewalls of the gate electrode 3132, spacers 3135 (sidewalls) formed with insulating films are provided.

The wiring layer 3120 is provided on the semiconductor substrate 3110 on which the MOS transistor 3130 and the like is provided. The wiring layer 3120 includes a conductive portion 3121 (e.g., wiring and vias) electrically connected to the MOS transistor 3130 and the like provided on the semiconductor substrate 3110, and an insulating portion 3122 covering the conductive portion 3121. By way of example, in FIG. 6, there is illustrated the conductive portion 3121 electrically connected to the source region 3133 and the drain region 3134 of the MOS transistor 3130. For the conductive portion 3121, various conductive materials such as Cu are used. For the insulating portion 3122, an inorganic insulating material such as silicon oxide or an organic insulating material such as resin is used.

The conductive portion 3121 of the outermost surface of the wiring layer 3120 includes portions that become terminals 3121a for external connection. A solder (e.g., the above-described solder 30) may be bonded on the terminals 3121a in advance before or when bonding the semiconductor chip 3100 to another electronic component.

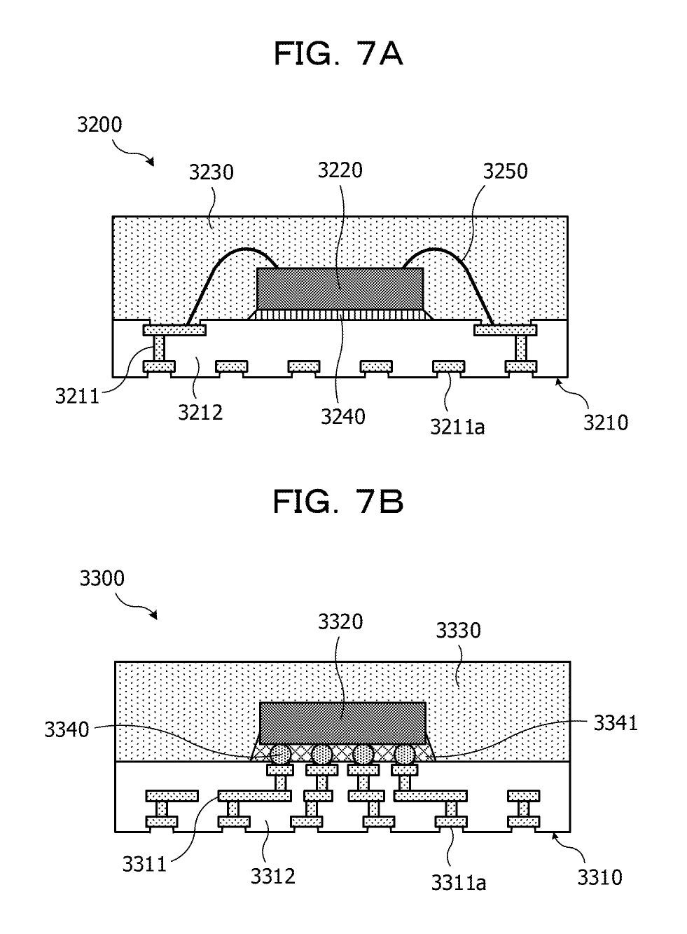

FIGS. 7A and 7B are diagrams illustrating an exemplary configuration of a semiconductor package. Each of FIGS. 7A and 7B is a cross-sectional view schematically illustrating a main part of a semiconductor package.

A semiconductor package 3200 illustrated in FIG. 7A includes a package substrate 3210 (e.g., a circuit board), a semiconductor chip 3220 mounted on the package substrate 3210, and a sealing layer 3230 sealing the semiconductor chip 3220.

As for the package substrate 3210, for example, a printed substrate is used. The package substrate 3210 includes a conductive portion 3211 (e.g., wiring and vias), and an insulating portion 3212 covering the conductive portion 3211. As for the conductive portion 3211, various conductive materials such as Cu are used. As for the insulating portion 3212, a resin material such as phenol resin, epoxy resin, and polyimide resin, a composite resin material in which the resin material is impregnated into glass fibers or carbon fibers or the like is used.

The semiconductor chip 3220 is adhered and fixed on the package substrate 3210 with a die-attach material 3240 such as resin or conductive paste, and electrically connected (wire-bonded) to the package substrate 3210 with wires 3250. The semiconductor chip 3220 and the wires 3250 on the package substrate 3210 are sealed with the sealing layer 3230. As for the sealing layer 3230, a resin material such as epoxy resin, a material containing an insulating filler in the resin material or the like is used.

The conductive portion 3211 of the surface of the package substrate 3210 opposite to the mounting surface of the semiconductor chip 3220 includes portions that become terminals 3211a for an external connection. A solder (e.g., the above-described solder 30) may be bonded on the terminals 3122a in advance before or when bonding the semiconductor package 3200 to another electronic component.

Further, on the package substrate 3210, a plurality of semiconductor chips 3220 may be mounted, and other electronic components such as chip capacitors in addition to the semiconductor chips 3220 may be mounted.

A semiconductor package 3300 illustrated in FIG. 7B includes a package substrate 3310 (e.g., a circuit board), a semiconductor chip 3320 mounted on the package substrate 3310, and a sealing layer 3330 covering the semiconductor chip 3320.

As for the package substrate 3310, for example, a printed substrate is used. The package substrate 3310 includes a conductive portion 3311 (e.g., wiring and vias) of Cu or the like, and an insulating portion 3312 of a resin material or the like, which covers the conductive portion 3311.

The semiconductor chip 3320 is electrically connected (e.g., flip-chip bonded) to the package substrate 3310 with the solder 3340 (e.g., bumps) provided therein. An under-fill material 3341 is filled between the package substrate 3310 and the semiconductor chip 3320. The semiconductor chip 3320 is sealed with a sealing layer 3330 on the package substrate 3310. As for the sealing layer 3330, a resin material such as epoxy resin, a material containing an insulating filler in the resin material or the like is used.

The conductive portion 3311 of the surface of the package substrate 3310 opposite to the mounting surface of the semiconductor chip 3320 includes portions that become terminals 3311a for an external connection. A solder (e.g., the above-described solder 30) is bonded on the terminals 3311a in advance before or when bonding the semiconductor package 3300 to another electronic component.

Further, on the package substrate 3310, a plurality of semiconductor chips 3320 may be mounted, and other electronic components such as chip capacitors in addition to the semiconductor chips 3320 may be mounted.

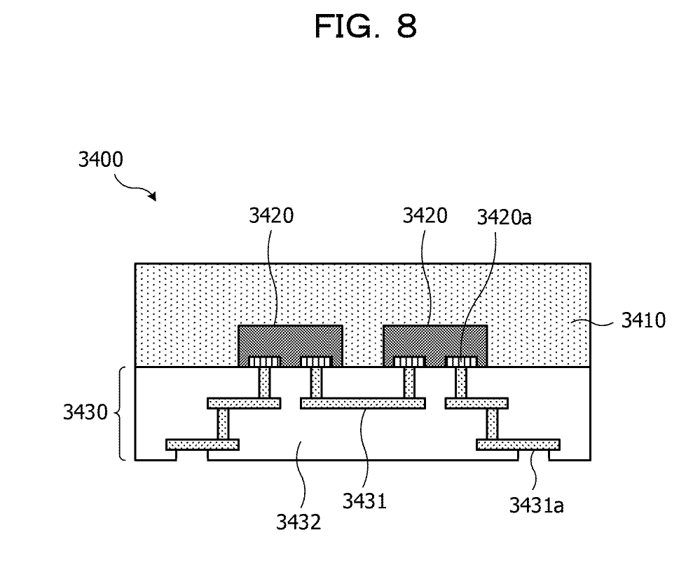

As for the semiconductor package, a so-called pseudo System on Chip (pseudo SoC) as illustrated in FIG. 8 may be used.

FIG. 8 is a diagram illustrating an exemplary configuration of a semiconductor package. FIG. 8 is a cross-sectional view schematically illustrating a main part of another example of a semiconductor package.

A semiconductor package 3400 illustrated in FIG. 8 includes a resin layer 3410, a plurality of semiconductor chips 3420 (e.g., two in this example) embedded in the resin layer 3410, and a wiring layer 3430 (e.g., a rewiring layer) provided on the resin layer 3410.

The semiconductor chips 3420 are embedded in the resin layer 3410 so as to expose the disposition surface of terminals 3420a. The wiring layer 3430 includes a conductive portion 3431 (e.g., rewiring and vias) of Cu or the like, and an insulating portion 3432 of a resin material or the like, which covers the conductive portion 3431.

The conductive portion 3431 of the outermost surface of the wiring layer 3430 includes portions that become terminals 3431a for an external connection. The positions of the terminals 3420a of the semiconductor chips 3420 are repositioned to the positions of the terminals 3431a for external connection by the conductive portion 3431. A solder (e.g., the above-described solder 30) is bonded on the terminals 3431a in advance before or when bonding the semiconductor chip 3400 to another electronic component.

Further, in the resin layer 3410, one or three or more semiconductor chips 3420 may be embedded, and other electronic components such as chip capacitors in addition to the semiconductor chips 3420 may be embedded.

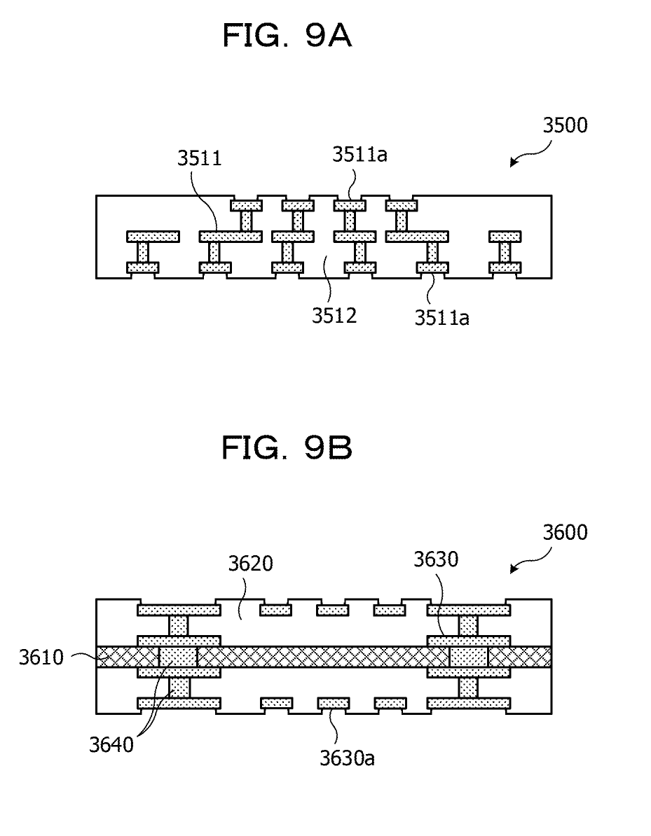

FIGS. 9A and 9B are diagrams illustrating an exemplary configuration of a circuit board. Each of FIGS. 9A and 9B is a cross-sectional view schematically illustrating a main part of an example of a circuit board.

FIG. 9A illustrates, as a circuit board 3500, a multilayer printed board including a plurality of wiring layers. In the same way as the package substrate 3210 illustrated in FIG. 7A and the package substrate 3310 illustrated in FIG. 7B, the circuit board 3500 includes a conductive portion 3511 (e.g., wiring and vias) of Cu or the like, and an insulating portion 3512 of a resin material or the like, which covers the conductive portion 3511.

The conductive portion 3511 of the outermost surface of the circuit board 3500 includes portions that become terminals 3511a for external connection. A solder is bonded on the terminals 3511a in advance before or when bonding the circuit board 3500 to another electronic component.

FIG. 9B illustrates, as a circuit board 3600, a build-up substrate formed by using a build-up process. The circuit board 3600 includes a core board 3610, an insulating layer 3620 provided on the core board 3610, conductive patterns 3630 provided through the insulating layer 3620, and vias 3640 for connection between different conductive patterns 3630. As for the core board 3610, a ceramic material, an organic material or the like is used. As for the insulating layer 3620, an insulating material such as prepreg is used. As for the conductive patterns 3630 and the vias 3640, a conductive material such as Cu is used.

The conductive patterns 3630 of the outermost surface of the circuit board 3600 include portions that become terminals 3630a for an external connection. A solder (e.g., the above-described solder 30) is bonded on the terminals 3630a in advance before or when bonding the circuit board 3600 to another electronic component.

For example, the semiconductor chip 3100 as illustrated in FIG. 6, the semiconductor packages 3200, 3300, and 3400 as illustrated in FIGS. 7A to 8, and the circuit boards 3500 and 3600 as illustrated in FIGS. 9A and 9B may be used in the electronic components 10 and 20 and the like.

As for a combination of the electronic components to be bonded, for example, there are a combination of a semiconductor chip and a circuit board, a combination of a semiconductor package and a circuit board, and a combination of a semiconductor chip and a semiconductor chip. In addition, as for a combination of electronic components to be bonded, there are a combination between semiconductor chips, a combination between semiconductor packages, and a combination between circuit boards.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A flux used for bonding a solder comprising:
75 wt % or more of ethylene glycol polymer represented by the following formula:
HO(CH₂CH₂O)ₙH . . . [n is an integer of 4 or more],
wherein an evaporation of the ethylene glycol polymer while being heated is terminated at a temperature equal to or greater than a bonding temperature of the solder.

2. The flux according to claim 1, wherein the ethylene glycol polymer has a molecular weight at which the evaporation of the ethylene glycol polymer while being heated is terminated at a temperature equal to or greater than the bonding temperature.

3. The flux according to claim 1, wherein the bonding temperature is in the range of 100° C. to 400° C.

4. The flux according to claim 1, wherein when the bonding temperature is in the range of 240° C. to 250° C., the molecular weight of the ethylene glycol polymer is in the range of 200 to 1000.

5. The flux according to claim 1, wherein the flux contains organic acid or organic acid anhydride.

6. A method of manufacturing an electronic device, the method comprising:
bonding a solder to a first terminal of a first electronic component using a flux,
wherein the flux contains 75 wt % or more of ethylene glycol polymer represented by the following formula:
HO(CH₂CH₂O)ₙH . . . [n is an integer of 4 or more],
wherein an evaporation of the ethylene glycol polymer while being heated is terminated at a temperature equal to or greater than a bonding temperature of the solder.

7. The method according to claim 6, wherein the flux is provided on at least one of the solder and the first terminal, and the solder is brought into contact with the first terminal to be heated at the bonding temperature.

8. The method according to claim 6, wherein the solder is disposed on a second terminal of a second electronic component.

9. The method according to claim 6, wherein after bonding the solder to the first terminal, cleaning is performed using water.
